(19) United States
(12) Patent Application Publication
(10) Pub. No.: US 2005/0191860 A1
(43) Pub. Date: Sep. 1, 2005

(54) Method for forming semiconductor device

(75) Inventors: Hideo Nakagawa, Shiga (JP); Masaru Sasago, Osaka (JP); Yoshihiko Hirai, Osaka (JP)

Correspondence Address: MCDERMOTT WILL & EMERY LLP, 600 13TH STREET, N.W., WASHINGTON, DC, 20005-3096, US

(73) Assignee: MATSUSHITA ELECTRIC INDUSTRIAL CO., LTD., Osaka (JP)

(21) Appl. No.: 11/102,445

(22) Filed: Apr. 7, 2005

Related U.S. Application Data
(63) Continuation of application No. PCT/JP04/08654, filed on Jun. 14, 2004.

(30) Foreign Application Priority Data
Jun. 20, 2003 (JP) 2003-175882

(51) Int. Cl. H01L 21/302

(52) U.S. Cl. 438/692; 438/715; 216/13

(57) ABSTRACT

A method for forming a semiconductor device includes the steps of forming, on a substrate, a flowable film made of an insulating material with flowability; planarizing a top face of the flowable film by pressing the flowable film with a pressing member; forming a solidified film by annealing the flowable film at a first temperature with the pressing member pressed against the flowable film; and forming a burned film with a flat top face by burning the solidified film through annealing of the solidified film at a second temperature higher than the first temperature.

### BACKGROUND OF THE INVENTION

Recently, semiconductor integrated circuit devices are processed according to a fine design rule in the vicinity of 100 nm or less.

In order to form a more refined resist pattern by lithography using light, it is necessary to reduce the wavelength of exposing light.

However, when the wavelength of exposing light is reduced, a focal depth is largely reduced, and therefore, it is indispensable to always keep flat the top face of an insulating film formed on a substrate. Therefore, in the formation of a semiconductor device having a fine design rule of 100 nm or less, a planarization technique for an insulating film on a substrate is very significant.

Currently, the mainly employed planarization technique for an insulating film in a semiconductor device with a design rule of 0.13 μm through 0.25 μm is known chemical mechanical polishing (CMP).

As a method for forming a flat insulating film, a method including the steps of forming a flowable film by supplying a material with flowability onto a substrate, pressing the flowable film with a flat pressing face of a pressing member for planarizing the surface of the flowable film and solidifying the flowable film whose surface has been planarized is known as disclosed in, for example, Patent document 1.

Now, the method for forming a flat insulating film disclosed in Patent document 1 (Japanese Laid-Open Patent Publication No. 2000-350934) will be described with reference to FIGS. 21A through 21C and 22A through 22C.

First, as shown in FIG. 21A, a material with flowability, such as a material in the form of a liquid or a gel, is supplied onto a step substrate composed of a substrate 101 of a semiconductor wafer and a layer having irregularities (hereinafter simply referred to as the step layer) 102 formed on the substrate 101, so as to form a film with flowability (hereinafter simply referred to as the flowable film) 103A on the step substrate.

Next, as shown in FIG. 21B, a flat pressing face of a pressing member 104 is opposed to the surface of the flowable film 103A, and thereafter, as shown in FIG. 21C, the flowable film 103A is pressed toward the step substrate by applying a pressure toward the substrate to the pressing member 104, so as to planarize the surface of the flowable film 103A.

In this case, the surface of the flowable film 103A is planarized over the whole surface of the substrate 101 simply by pressing the flowable film 103A with the pressing face of the pressing member 104.

Next, as shown in FIG. 22A, with the flowable film 103A pressed toward the substrate 101 with the pressing member 104, the flowable film 103A is annealed for causing a chemical reaction within the flowable film 103A, so as to solidify the flowable film 103A. Thus, a film having been solidified (hereinafter simply referred to as the solidified film) 103B having a flat top face is formed.

Then, after completing the annealing, the temperature of the solidified film 103B is lowered to room temperature, and thereafter, as shown in FIG. 22B, the pressing member 104 is moved away from the solidified film 103B. Thus, as shown in FIG. 22C, the solidified film 103B having a flat top face can be formed on the step substrate.

### SUMMARY OF THE INVENTION

An object of the invention is forming, through a small number of processes, an insulating film that has a high film quality with a uniform structure of a basic skeleton and has a minimum global level difference.

In order to achieve the object, the first method for forming a semiconductor device of this invention includes the steps of forming, on a substrate, a flowable film made of an insulating material with flowability; planarizing a top face of the flowable film by pressing the flowable film with a pressing member; forming a solidified film by annealing the flowable film at a first temperature with the pressing member pressed against the flowable film; and forming a burned film with a flat top face by burning the solidified film through annealing of the solidified film at a second temperature higher than the first temperature.

In the first method for forming a semiconductor device, after pressing the flowable film with the pressing member, the solidifying process and the burning process are performed. Therefore, an insulating film made of the burnt film with a minimum global level difference and a flat top face can be formed through a small number of processes. Also, the annealing is performed on the flowable film at the first temperature that is a relatively low temperature, and thus, the basic skeleton of the solidified film (such as a polymer skeleton of an organic film, a siloxane skeleton of a silicon oxide film or an organic-inorganic film, or a resin skeleton of a resist film) is formed. Thereafter, the annealing is performed on the solidified film at the second temperature that is a relatively high temperature, so as to vaporize porogen such as an acrylic polymer, a remaining solvent or the like from the solidified film. Therefore, as compared with the case where formation of a basic skeleton and vaporization of the porogen, a remaining solvent or the like are performed in parallel, the structure of the basic skeleton of the insulating film made of the burnt film is uniform, resulting in improving the film quality of the insulating film. Accordingly, the dielectric constant of the insulating film is uniform within the whole film, and the insulating film attains high reliability.

The second method for forming a semiconductor device of this invention includes the steps of forming a flowable film made of an insulating material with flowability on a substrate including a interconnect; planarizing a top face of the flowable film by pressing the flowable film with a pressing member; forming a solidified film by annealing the flowable film at a first temperature with the pressing member pressed against the flowable film; forming a burned film with a flat top face by burning the solidified film through annealing of the solidified film at a second temperature higher than the first temperature; forming a via hole in the burned film; and forming a plug connected at least to the interconnect by filling the via hole with a metal material.

In the second method for forming a semiconductor device, after pressing the flowable film with the pressing member, the solidifying process and the burning process are performed. Therefore, an insulating film made of the burnt film with a minimum global level difference and a flat top face can be formed through a small number of processes. Also, the annealing is performed on the flowable film at the first temperature that is a relatively low temperature, and thus, the basic skeleton of the solidified film is formed. Thereafter, the annealing is performed on the solidified film at the second temperature that is a relatively high temperature, so as to vaporize porogen such as an acrylic polymer, a remaining solvent or the like from the solidified film. Therefore, the structure of the basic skeleton of the insulating film made of the burnt film is uniform, resulting in improving the film quality of the insulating film. Accordingly, the dielectric constant of the insulating film is uniform within the whole film, and the insulating film attains high reliability.

The third method for forming a semiconductor device of this invention includes the steps of forming a flowable film made of an insulating material with flowability on a substrate including a plug; planarizing a top face of the flowable film by pressing the flowable film with a pressing member; forming a solidified film with a flat top face by annealing the flowable film at a first temperature with the pressing member pressed against the flowable film; forming a burned film with a flat top face by burning the solidified film through annealing of the solidified film at a second temperature higher than the first temperature; forming a groove in the burned film; and forming a interconnect connected at least to the plug by filling the groove with a metal material.

In the third method for forming a semiconductor device, after pressing the flowable film with the pressing member, the solidifying process and the burning process are performed. Therefore, an insulating film made of the burnt film with a minimum global level difference and a flat top face can be formed through a small number of processes. Also, the annealing is performed on the flowable film at the first temperature that is a relatively low temperature, and thus, the basic skeleton of the solidified film is formed. Thereafter, the annealing is performed on the solidified film at the second temperature that is a relatively high temperature, so as to vaporize porogen such as an acrylic polymer, a remaining solvent or the like from the solidified film. Therefore, the structure of the basic skeleton of the insulating film made of the burnt film is uniform, resulting in improving the film quality of the insulating film. Accordingly, the dielectric constant of the insulating film is uniform within the whole film, and the insulating film attains high reliability.

In the first method for forming a semiconductor device, the first temperature is preferably approximately 150° C. through approximately 300° C.

Thus, the basic skeleton of the flowable film can be formed without vaporizing the porogen or the like included in the flowable film.

In the second method for forming a semiconductor device, the first temperature is approximately 150° C. through approximately 300° C. and the second temperature is approximately 350° C. through approximately 450° C.

Thus, the basic skeleton of the flowable film can be formed without vaporizing the porogen or the like included in the flowable film.

In the first method for forming a semiconductor device, the second temperature is preferably approximately 350° C. through approximately 450° C.

Thus, the porogen or the like can be vaporized from the solidified film without degrading the film quality of the solidified film and also the film quality of the burnt film.

In the first method for forming a semiconductor device, the insulating material with flowability is preferably in the form of a liquid or a gel.

Thus, the flowable film can be easily and definitely formed.

In the first method for forming a semiconductor device, in the step of forming a flowable film, the flowable film is preferably formed on the substrate by supplying the insulating material with flowability onto the substrate rotated.

Thus, the thickness of the flowable film can be made uniform.

In the first method for forming a semiconductor device, in the step of forming a flowable film, the flowable film is preferably formed on the substrate by supplying the insulating material with flowability onto the substrate and rotating the substrate after the supply.

Thus, the thickness of the flowable film can be made uniform.

In the first method for forming a semiconductor device, in the step of forming a flowable film, the flowable film is preferably formed on the substrate by supplying, in the form of a shower or a spray, the insulating material with flowability onto the substrate rotated.

Thus, the flowable film can be definitely formed in a comparatively small thickness.

In the first method for forming a semiconductor device, in the step of forming a flowable film, the flowable film is preferably formed on the substrate by supplying the insulating material with flowability from a fine spray vent of a nozzle onto the substrate with the nozzle having the fine spray vent and the substrate relatively moved along plane directions.

Thus, the thickness of the flowable film can be controlled to be a desired thickness by adjusting the relative moving rates of the nozzle and the substrate. Also, the degree of the flowability of the flowable film can be changed by adjusting the viscosity of the material with flowability. Furthermore, the process speed can be controlled by adjusting the number of nozzles.

In the first method for forming a semiconductor device, in the step of forming a flowable film, the flowable film is preferably formed on the substrate by supplying the insulating material with flowability having been adhered to a surface of a roller onto the substrate with the roller rotated.

Thus, the thickness of the flowable film can be controlled by adjusting a distance between the roller and the substrate and a force for pressing the roller against the substrate. Also, a material with flowability and high viscosity can be used.

Each of the first method for forming a semiconductor device preferably further includes, between the step of forming a flowable film and the step of planarizing a top face of the flowable film, a step of selectively removing a peripheral portion of the flowable film.

Thus, the peripheral portion of the substrate can be mechanically held in the process for forming the burnt film with ease.

In the case of the first method for forming a semiconductor device includes the step of selectively removing a peripheral portion of the flowable film, this step is preferably performed by supplying a solution for dissolving the insulating material with flowability onto the peripheral portion of the flowable film with the flowable film rotated.

Thus, the flowable film can be definitely removed from a peripheral portion of a substrate in the plane shape of a circle or a polygon with a large number of vertexes.

In the case of the first method for forming a semiconductor device includes the step of selectively removing a peripheral portion of the flowable film, this step is preferably performed by modifying the peripheral portion of the flowable film through irradiation with light and removing the modified peripheral portion.

Thus, the flowable film can be definitely removed from a peripheral portion of a substrate not only in the plane shape of a circle or a polygon with a large number of vertexes but also in the shape of a polygon with a small number of vertexes such as a triangle or a rectangle.

In the first method for forming a semiconductor device, in the step of planarizing a top face of the flowable film, it is preferred that a plurality of distances between a surface of the substrate and the pressing member are measured, and that the flowable film is pressed with the pressing member in such a manner that the plurality of distances are equal to one another.

Thus, a distance of the surface of the flowable film from the surface of the substrate can be always made uniform, and therefore, an operation for making uniform a distance between the surface of the substrate and the pressing member of the pressing member every given period of time can be omitted.

In the case of the first method for forming a semiconductor device, in the case where the plurality of distances between the surface of the substrate or the stage and the pressing face are measured, the plurality of distances are preferably measured by measuring capacitance per unit area in respective measurement positions.

Thus, the plural distances can be easily and definitely measured.

In the first method for forming a semiconductor device, in the step of planarizing a top face of the flowable film, it is preferred that a plurality of distances between a surface of a stage where the substrate is placed and the pressing member are measured, and that the flowable film is pressed with the pressing member in such a manner that the plurality of distances are equal to one another.

Thus, a distance of the surface of the flowable film from the surface of the substrate can be always made uniform, and therefore, an operation for making uniform a distance between the surface of the substrate and the pressing member of the pressing member every given period of time can be omitted.

In the case of the first method for forming a semiconductor device, in the case where the plurality of distances between the surface of the substrate or the stage and the pressing member are measured, the plurality of distances are preferably measured by measuring capacitance per unit area in respective measurement positions.

Thus, the plural distances can be easily and definitely measured.

In the first method for forming a semiconductor device, the pressing member of the pressing member preferably has a hydrophobic property.

Thus, the pressing member can be easily moved away from the solidified film, and therefore, a solidified film with fewer defects and also a burnt film with fewer defects can be formed.

In the first method for forming a semiconductor device, it is preferred that the insulating material with flowability is a photo-setting resin, and that the step of forming a solidified film includes a sub-step of irradiating the flowable film with light.

Thus, the flowable film can be easily and rapidly solidified through a photochemical reaction and a thermal chemical reaction.

In the first method for forming a semiconductor device, the insulating material with flowability is preferably an organic material, an inorganic material, an organic-inorganic material, a photo-setting resin or a photosensitive resin.

In the first method for forming a semiconductor device, in the step of forming a burnt film, the solidified film is preferably annealed at the second temperature with the pressing member pressed against the solidified film.

Thus, the flatness of the solidified film with a flat top face can be accurately kept.

In the first method for forming a semiconductor device, in the step of forming a burnt film, the solidified film is preferably annealed at the second temperature with the pressing member moved away from the solidified film.

Thus, the porogen, the remaining solvent or the like included in the solidified film can be easily vaporized.

In the first method for forming a semiconductor device, the burnt film is preferably a porous film.

Thus, an insulating film made of the burnt film with a low dielectric constant can be formed.

In the second method for forming a semiconductor device, the burnt film preferably has a dielectric constant of approximately 4 or less.

Thus, the dielectric constant of the insulating film can be definitely lowered, so as to reduce capacitance between metal interconnects.

The second method for forming a semiconductor device preferably further includes, before the step of forming a flowable film, a step of forming the buried interconnect exposed on the substrate by forming a buried interconnect in an organic film formed on the substrate and removing the organic film.

In the second method for forming a semiconductor device, the organic film is preferably removed by wet etching in the step of forming the buried interconnect or the buried plug.

The third method for forming a semiconductor device preferably further includes, before the step of forming a flowable film, a step of forming the buried plug exposed on the substrate by forming a buried plug in an organic film formed on the substrate and removing the organic film.

In the third method for forming a semiconductor device, the organic film is preferably removed by dry etching in the step of forming the buried interconnect or the buried plug.

Furthermore, this invention gives one solution for the problem that the cost of the formation process for the semiconductor device is high because the number of processes is large, in the case where multilayered interconnects are formed by a damascene method

Also, this invention gives one solution for the problem that the heights of the multilayered interconnect from a substrate is largely varied, in the case where multilayered interconnects are formed by repeating the damascene method in which a buried interconnect is formed by depositing a metal film on an insulating film for filling a concave portion formed in the insulating film and removing an unnecessary portion of the metal film by the CMP, global level differences are accumulated in the CMP.

Furthermore, in the case where the flat insulating film obtained by the method disclosed in Patent document 1 is used as an interlayer insulating film of a semiconductor device, in order to guarantee the stability of the film quality of the insulating film, an annealing curing process generally performed at a temperature of approximately 400° C. is necessary in the solidifying process.

However, in some insulating materials, the structure of the basic skeleton of the insulating film becomes locally ununiform when they are annealed at a temperature of 350° C. or more in the solidifying process, which leads to degradation of the film quality that the dielectric coefficient of the insulating film is varied in accordance with the position within the insulation film.

In contrast to Patent document 1, the insulating film related to this invention can attain sufficient reliability, and hence, this invention can prevent degrading the performance and the reliability of the semiconductor device.

### BRIEF DESCRIPTION OF THE DRAWINGS

FIGS. 1A through 1D are cross-sectional views for showing procedures in a method for forming a semiconductor device according to Embodiment 1.

FIGS. 2A through 2C are cross-sectional views for showing other procedures in the method for forming a semiconductor device according to Embodiment 1.

FIG. 3A is a flowchart for showing a sequence of a conventional method for forming a semiconductor device and FIG. 3B is a flowchart for showing a sequence of the method for forming a semiconductor device according to Embodiment 1 or 2.

FIGS. 4A through 4C are cross-sectional views for showing procedures in Example 1 employed in the method for forming a semiconductor device according to Embodiment 1 or 2.

FIGS. 5A and 5B are cross-sectional views for showing procedures in Example 2 employed in the method for forming a semiconductor device according to Embodiment 1 or 2.

FIGS. 6A and 6B are cross-sectional views for showing procedures in Example 3 employed in the method for forming a semiconductor device according to Embodiment 1 or 2.

FIGS. 7A and 7B are cross-sectional views for showing procedures in Example 4 employed in the method for forming a semiconductor device according to Embodiment 1 or 2.

FIGS. 8A through 8C are cross-sectional views for showing procedures in a method for forming a semiconductor device according to Embodiment 3.

FIGS. 9A through 9C are cross-sectional views for showing other procedures in the method for forming a semiconductor device according to Embodiment 3.

FIGS. 10A and 10B are cross-sectional views for showing procedures in a method for forming a semiconductor device according to Embodiment 4.

FIGS. 11A and 11B are cross-sectional views for showing other procedures in the method for forming a semiconductor device according to Embodiment 4.

FIGS. 12A and 12B are cross-sectional views for showing procedures in a method for forming a semiconductor device according to Embodiment 5.

FIGS. 13A through 13F are cross-sectional views for showing procedures in a method for forming a semiconductor device according to Embodiment 6.

FIGS. 14A through 14D are cross-sectional views for showing other procedures in the method for forming a semiconductor device according to Embodiment 6.

FIGS. 15A through 15D are cross-sectional views for showing other procedures in the method for forming a semiconductor device according to Embodiment 6.

FIGS. 16A through 16D are cross-sectional views for showing other procedures in the method for forming a semiconductor device according to Embodiment 6.

FIGS. 17A through 17F are cross-sectional views for showing procedures in a method for forming a semiconductor device according to Embodiment 7.

FIGS. 18A through 18D are cross-sectional views for showing other procedures in the method for forming a semiconductor device according to Embodiment 7.

FIGS. 19A through 19D are cross-sectional views for showing other procedures in the method for forming a semiconductor device according to Embodiment 7.

FIGS. 20A through 20D are cross-sectional views for showing other procedures in the method for forming a semiconductor device according to Embodiment 7.

FIGS. 21A through 21C are cross-sectional views for showing procedures in a conventional method for forming a semiconductor device.

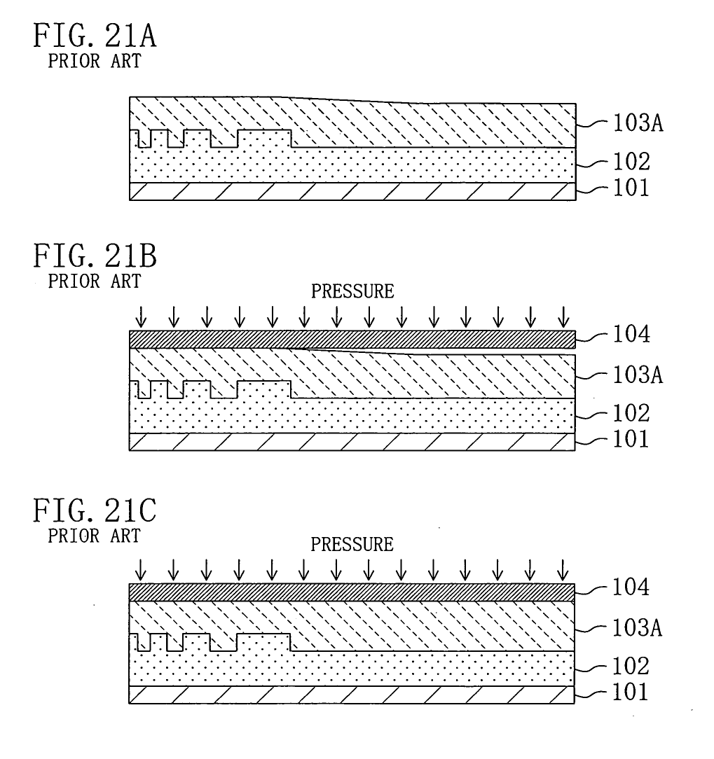

FIGS. 22A through 22C are cross-sectional views for showing other procedures in the conventional method for forming a semiconductor device.

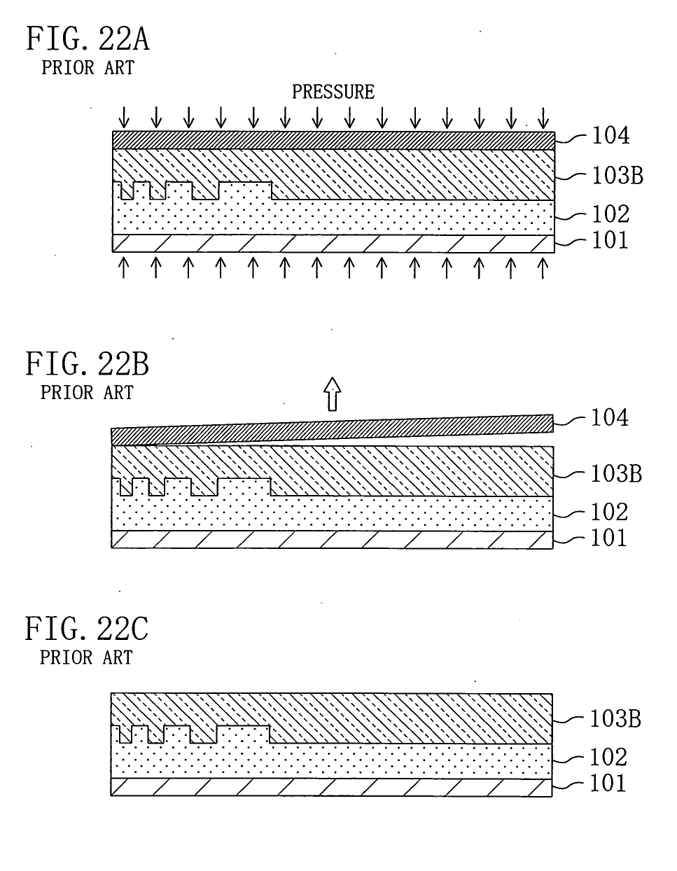

### DESCRIPTION OF THE EMBODIMENTS

(Embodiment 1)

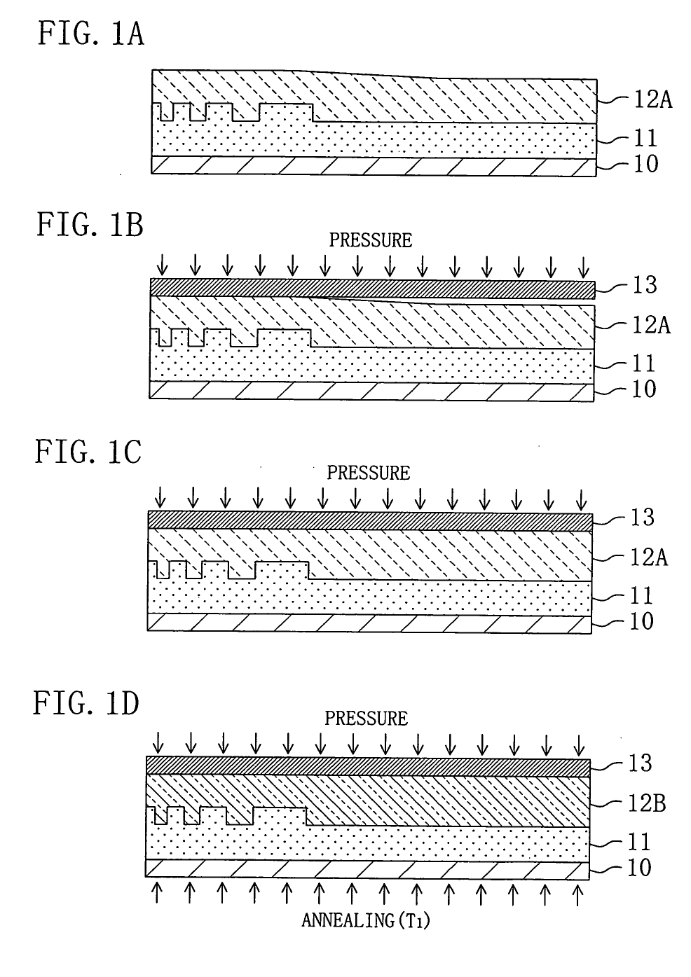

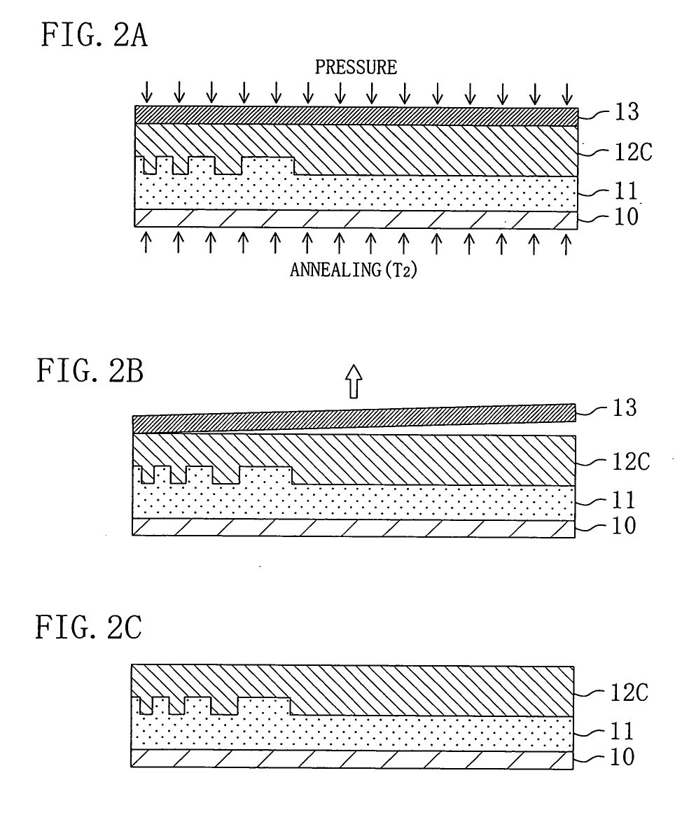

A method for forming a semiconductor device according to Embodiment 1 will now be described with reference to FIGS. 1A through 1D and 2A through 2C.

First, as shown in FIG. 1A, after forming a step layer 11 on a substrate 10 of a semiconductor wafer, a material with flowability, such as a material in the form of a liquid or a gel, is supplied onto the step layer 11, so as to form a flowable film 12A. The plane shape of the substrate 10 is not particularly specified and may be any shape including a circle, a polygon and the like.

In general, annealing is performed at approximately 80° C. through 120° C. in order to vaporize a part or most of a solvent included in the flowable film 12A formed above the substrate 10. This annealing is generally designated as pre-bake, and the temperature of the pre-bake may be set so that the flowability of the flowable film 12A can be kept in a planarizing process subsequently performed. Specifically, the temperature may be set in accordance with the characteristics (such as the boiling point) of the solvent used for supplying the material with flowability, and the pre-bake may be omitted in some cases.

The flowable film 12A may be, for example, an organic film, an inorganic film, an organic-inorganic film (organic-inorganic hybrid film), a photo-setting resin film that is cured through irradiation with light, a photosensitive resin film such as a resist film, a porous film having a large number of pores with a diameter of approximately 1 nm through 10 nm therein, or the like.

A method for forming the flowable film 12A may be a spin coating method, a microscopic spraying method, a rotation roller method or the like, the thickness of the flowable film 12A is adjusted differently depending upon the employed method, and the film thickness can be adjusted by selecting the method for forming the flowable film 12A. The method for forming the flowable film 12A will be described in detail in Examples 1 through 4 below.

In the case where the flowable film 12A is used as an interlayer film of multilayered interconnects, the material with flowability is preferably an insulating material.

Next, as shown in FIG. 1B, a flat pressing face of a pressing member 13 is opposed to the surface of the flowable film 12A, and thereafter, as shown in FIG. 1C, a pressure toward the substrate is applied to the pressing member 13, so as to planarize the whole top face of the flowable film 12A.

In this case, merely by pressing the flowable film 12A with the pressing face of the pressing member 13, the whole top face of the flowable film 12A is planarized. However, when the press with the pressing member 13 is intermitted, the flowable film 12A is changed into an energetically stable shape owing to the surface tension of the flowable film 12A.

Therefore, as shown in FIG. 1D, with the pressing member 13 pressed against the flowable film 12A, the flowable film 12A is annealed at a first temperature (T1) so as to cause a chemical reaction within the flowable film 12A. Thus, the flowable film 12A is solidified, thereby forming a solidified film 12B made of the flowable film 12A solidified and having a flat top face. The first temperature (T1) is preferably approximately 150° C. through approximately 300° C. and is more preferably approximately 200° C. through approximately 250° C. In this manner, the basic skeleton of the flowable film 12A, such as a polymer skeleton or a siloxane skeleton, is definitely formed. In the solidifying process, the annealing is performed with a hot plate set to a desired temperature for approximately 2 through 3 minutes.

Next, as shown in FIG. 2A, with the pressing member 13 pressed against the solidified film 12B, the solidified film 12B is annealed at a second temperature (T2) higher than the first temperature (T1) for burning the solidified film 12B. Thus, a burnt film 12C made of the solidified film 12B burnt and having a flat top face is formed. The second temperature (T2) is preferably approximately 350° C. through approximately 450° C. In this manner, porogen or the like is vaporized from the solidified film 12B where the basic skeleton has been formed, and hence, the burnt film 12C with a uniform film quality can be obtained. In the process for forming the burnt film 12C, the annealing is performed with a hot plate set to a desired temperature for approximately 2 through approximately 15 minutes.

Next, after lowering the temperature of the burnt film 12C to a temperature range between approximately 100° C. and room temperature, as shown in FIG. 2B, the pressing member 13 is moved away from the burnt film 12C, and thereafter, the temperature of the burnt film 12C is ultimately lowered to room temperature. Thus, as shown in FIG. 2C, the burnt film 12C that is flat in the whole top face is obtained.

In order to provide the pressing face of the pressing member 13 with a hydrophobic property, the pressing face is preferably subjected to a Teflon (registered trademark) coating treatment or a surface treatment with a silicon coupling material. Thus, the pressing member 13 can be easily moved away from the burnt film 12C, and hence, the burnt film 12C with fewer defects can be formed.

Now, materials with flowability will be described.

The material with flowability used for forming an organic film is, for example, an aromatic polymer having aryl ether as a principal skeleton, and specific examples are FLARE and GX-3 (manufactured by Honeywell) and SiLK (manufactured by Dow Chemical).

The material with flowability used for forming an inorganic film is, for example, HSQ (hydrogen silsquioxane) or organic SOG such as an alkylsiloxane polymer, and a specific example of the HSQ is Fox (manufactured by Dow Corning) and a specific example of the organic SOG is HSG-RZ25 (manufactured by Hitachi Chemical Co., Ltd.).

The material with flowability used for forming an organic-inorganic film is, for example, organic siloxane having an organic group such as a methyl group in a siloxane skeleton, and a specific example is HOSP (hybrid organic siloxane polymer) (manufactured by Honeywell).

The material with flowability used for forming a photo-setting resin film is, for example, PDGI (polydimethyl glutar imide), and a specific example is SAL101 (manufactured by Shipley Far East).

The material with flowability used for forming a photosensitive resin film may be a general resist material used in the lithography.

The material with flowability used for forming a porous film is, for example, an organic, inorganic or organic-inorganic material having pores, a specific example of the organic material having pores is Porous FLARE (manufactured by Honeywell), a specific example of the inorganic material having pores is XLK (manufactured by Dow Corning) having pores in HSQ (hydrogen silsquioxane), and specific examples of the organic-inorganic material having pores are Nanoglass (manufactured by Honeywell) and LKD-5109 (manufactured by JSR).

When the burnt film 12C obtained by solidifying and burning the flowable film 12A made of any of the aforementioned materials is used as an interlayer insulating film of multilayered interconnects, an interlayer insulating film that is dense and has a lower dielectric constant than a general silicon oxide film (with a dielectric constant of approximately 4) can be obtained. Therefore, a film suitable to a semiconductor device refined to 100 nm or less can be realized. In particular, when a porous film is used as the burnt film 12C, an interlayer insulating film with a very low dielectric constant of 2 or less can be realized.

(Embodiment 2)

A method for forming a semiconductor device according to Embodiment 2 will now be described with reference to FIGS. 1A through 1D and 2A through 2C.

Since the basic process sequence of Embodiment 2 is almost the same as that of Embodiment 1, a difference from that of Embodiment 1 will be principally described below.

First, in the same manner as in Embodiment 1, after forming a step layer 11 on a substrate 10, a flowable film 12A is formed on the step layer 11. Thereafter, a pressing member 13 is pressed against the flowable film 12A, so as to planarize the whole top face of the flowable film 12A.

Next, with the pressing member 13 pressed against the flowable film 12A, the flowable film 12A is annealed at a first temperature (T1), so as to form a solidified film 12B having a flat top face.

Then, after moving the pressing member 13 away from the solidified film 12B, the solidified film 12B is annealed at a second temperature (T2) higher than the first temperature (T1) for burning the solidified film 12B, thereby forming a burnt film 12C made of the burnt solidified film 12B. Thereafter, the temperature of the burnt film 12C is lowered to approximately room temperature. Thus, the burnt film 12C having a flat top face is formed.

A difference between Embodiment 1 and Embodiment 2 is that the solidified film 12B is burnt with the pressing face of the pressing member 13 pressed against the solidified film 12B in Embodiment 1 while it is burnt with the pressing face of the pressing member 13 moved away from the solidified film 12B in Embodiment 2. Accordingly, in Embodiment 2, it is necessary to perform the annealing with a hot plate in the solidifying process but the annealing can be performed with a hot plate or a furnace in the burning process.

Embodiment 2 is more effective than Embodiment 1 in the case where a solidified film largely outgassing is annealed in the burning process. In a general film, the concentration of a remaining solvent in the film can be controlled through the pre-bake, and therefore, the film minimally outgases in the burning process, but depending upon the composition of the film, it may outgas in the burning process where the annealing is performed at a comparatively high temperature. In such a case, there may arise a problem of uniformity or stability of the burnt film 12C when the burning process of Embodiment 1 is performed, and hence, the burning process of Embodiment 2 is preferably performed. In particular, this effect is exhibited when the burnt film 12C is a porous film. In a porous film, most of the basic structure of the film is formed through the annealing performed at the first temperature (T1) in the solidifying process, and a pore forming material added for forming pores is vaporized through the annealing performed at the second temperature (T2) in the burning process. Therefore, the burning process of Embodiment 2 in which the film is burnt with the pressing member 13 moved away from the solidified film 12B is suitable. Even in a porous film, if it is an optimal film in which the basic skeleton of the film is formed and most of a pore forming material is vaporized in the solidifying process, a good burnt film 12C can be obtained even by employing the burning process of Embodiment 1.

In Embodiment 1 or 2, the annealing temperature of the burning process (the second temperature) is set to be higher than the annealing temperature of the solidifying process. (the first temperature). In the case where the burnt film 12C is used as an insulating film of a semiconductor device, the annealing temperature of the solidifying process (the first temperature) is preferably approximately 150° C. through 300° C., and the annealing temperature of the burning process (the second temperature) is preferably approximately 350° C. through 450° C.

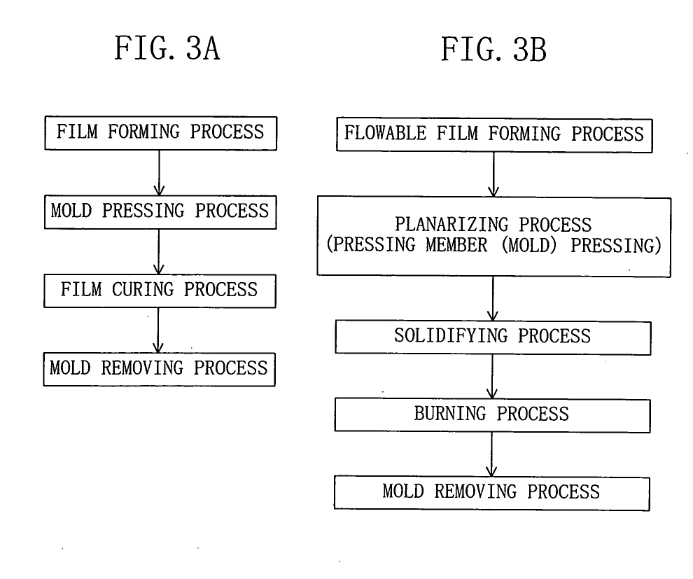

Next, a difference between a conventional method for forming a semiconductor device and the present method for forming a semiconductor device will be described with reference to FIGS. 3A and 3B.

As shown in FIG. 3A, in the conventional method for forming a semiconductor device, a film having a flat top face is formed through one annealing in a film curing process performed after pressing with a pressing member (a mold). On the contrary, as shown in FIG. 3B, in the present method for forming a semiconductor device, after pressing with the pressing member (a mold) (after the planarizing process), a flat burnt film 12C is formed through the annealing performed in the two stages in the solidifying process and the burning process.

### <EXAMPLE 1>

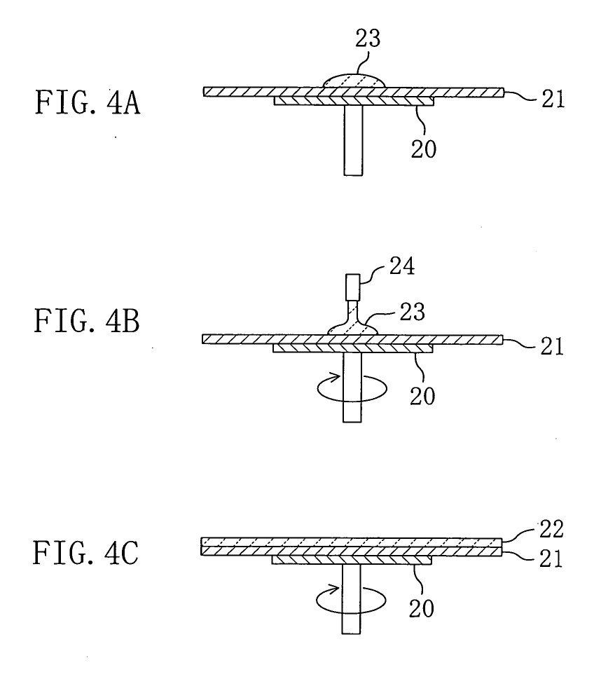

As a method for forming a flowable film used in Embodiment 1 or 2, a first spin coating method will now be described with reference to FIGS. 4A through 4C.

First, as shown in FIG. 4A, after holding a substrate 21 through vacuum adsorption on a rotatable stage 20, an appropriate amount of material 23 with flowability is dropped on the substrate 21, and thereafter, the stage 20 is rotated. Alternatively, as shown in FIG. 4B, after holding a substrate 21 through vacuum adsorption on a rotatable stage 20, a material 23 with flowability is supplied from a dropping nozzle 24 onto the substrate 21 while rotating the stage 20 together with the substrate 21.

In this manner, a flowable film 22 is formed on the substrate 21 as shown in FIG. 4C.

In either of the method shown in FIG. 4A and the method shown in FIG. 4B, when the viscosity of the material 23 with flowability and the rotation speed of the stage 20 are optimized, the flowable film 22 can attain hardness suitable for the process for transferring the flat surface of the pressing face of the pressing member 13 (see FIG. 1B or 2B) onto the flowable film 22.

It is noted that the method of Example 1 is suitable to a case where the flowable film 22 is formed in a comparatively large thickness.

### <EXAMPLE 2>

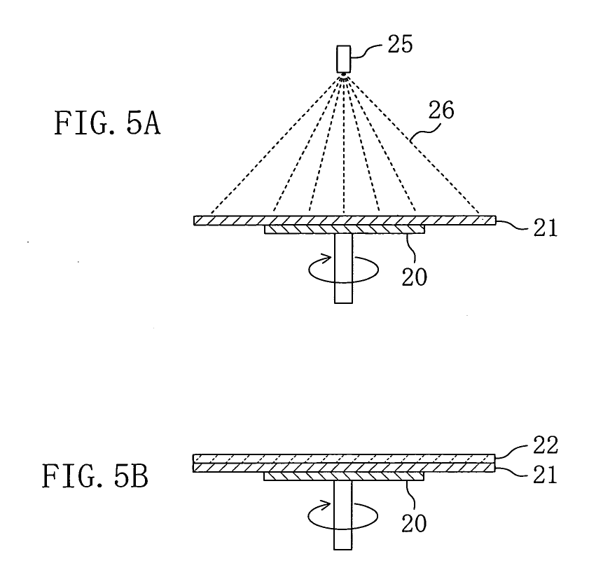

As a method for forming a flowable film used in Embodiment 1 or 2, a second spin coating method will now be described with reference to FIGS. 5A and 5B.

First, as shown in FIG. 5A, after holding a substrate 21 through vacuum adsorption on a rotatable stage 20, a material 26 with flowability is supplied in the form of a shower or spray from a spray nozzle 25 onto the substrate 21 while rotating the stage 20 together with the substrate 21.

After supplying a desired amount of material 26 with flowability, the stage 20 is continuously rotated for a predetermined period of time. Thus, a flowable film 22 is formed on the substrate 21 as shown in FIG. 5B.

The method of Example 2 is suitable to a case where the flowable film 22 is formed in a comparatively small thickness.

### <EXAMPLE 3>

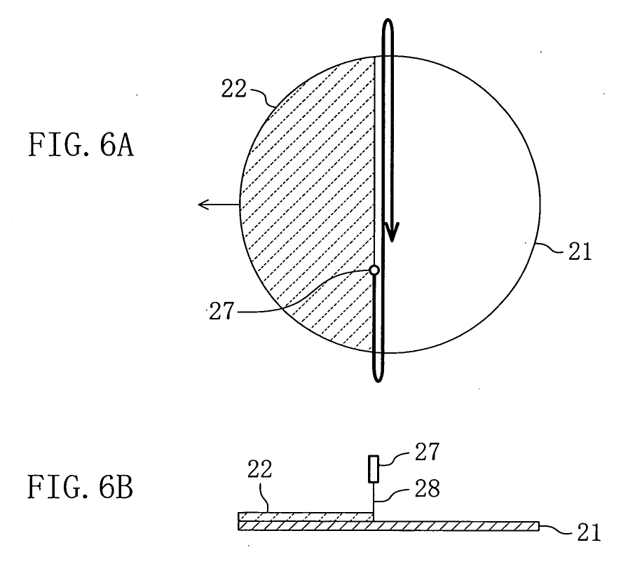

As a method for forming the flowable film used in Embodiment 1 or 2, a microscopic spraying method will now be described with reference to FIGS. 6A and 6B.

First, as shown in FIG. 6A, a material 28 with flowability is supplied from a dropping nozzle 27 onto a substrate 21 by a given amount at a time while moving the substrate 21 along one of the two perpendicular directions of the two-dimensional rectangular coordinate system, for example, along the lateral direction of FIG. 6A and moving the dropping nozzle 27 along the other of the two perpendicular directions, for example, along the longitudinal direction of FIG. 6A. In other words, an operation for moving the substrate 21 by a given distance toward the leftward direction in FIG. 6A and stopping it is repeatedly performed, and while the substrate 21 is stopped, the material 28 with flowability is supplied from the dropping nozzle 27 onto the substrate 21 by a given amount at a time while moving the dropping nozzle 27 along the longitudinal direction in FIG. 6A.

In this manner, a flowable film 22 is formed on the substrate 21 as shown in FIG. 6B.

In the method of Example 3, the thickness of the flowable film 22 can be controlled over a range from a small thickness to a large thickness by adjusting the amount of material 28 with flowability supplied from the dropping nozzle 27 and the moving rate of the dropping nozzle 27.

Also, the degree of the flowability of the flowable film 22 can be changed by adjusting the viscosity of the material 28 with flowability supplied from the dropping nozzle 27.

Furthermore, the process speed can be controlled by adjusting the number of dropping nozzles 27.

### <EXAMPLE 4>

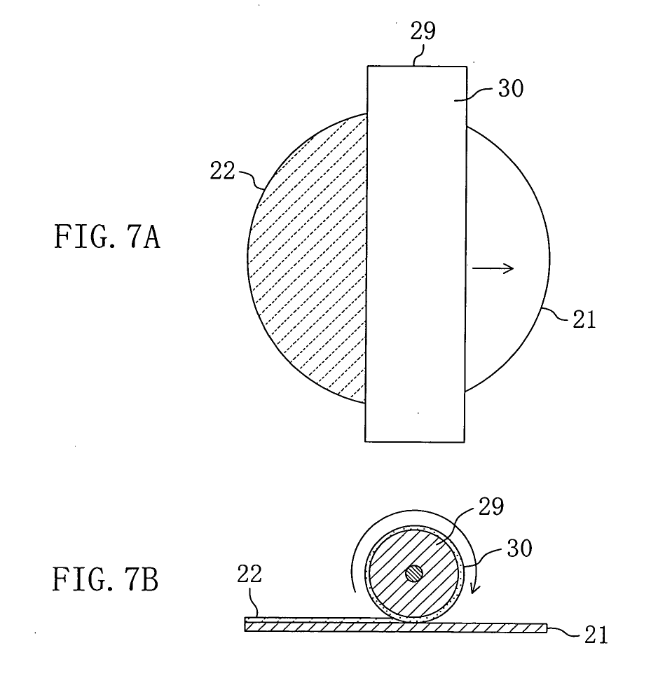

As a method for forming a flowable film used in Embodiment 1 or 2, a rotation roller method will now be described with reference to FIGS. 7A and 7B.

As shown in FIGS. 7A and 7B, with a material 30 with flowability uniformly adhered onto the peripheral face of a rotation roller 29, the rotation roller 29 is rotationally moved on the surface of a substrate 21.

In this manner, the material 30 with flowability is adhered onto the surface of the substrate 21, and hence, a flowable film 22 is formed on the substrate 21 as shown in FIG. 7B.

In the method of Example 4, the thickness of the flowable film 22 can be controlled by adjusting the distance between the rotation roller 29 and the substrate 21 and a force for pressing the rotation roller 29 against the substrate 21.

Also, the method of Example 4 is suitable to a case where the material 30 with flowability is in the form of a highly viscous liquid or a gel.

(Embodiment 3)

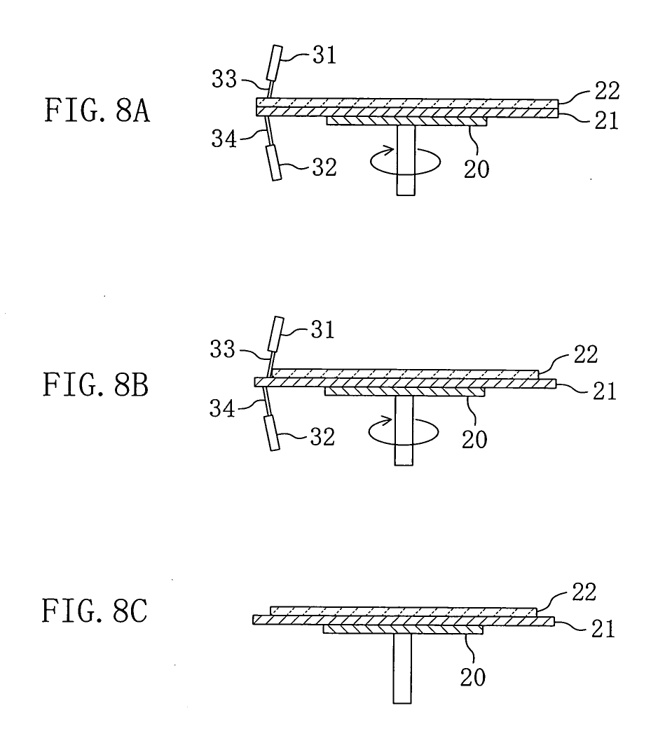

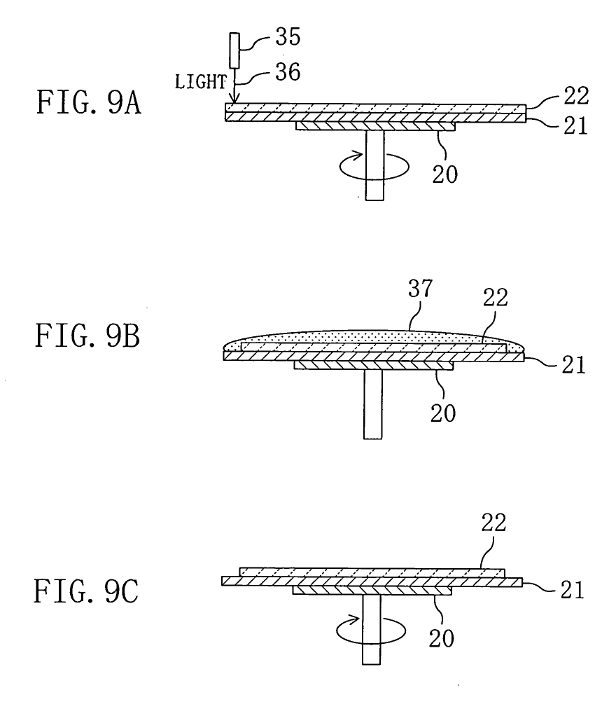

A method for forming a semiconductor device according to Embodiment 3 will now be described with reference to FIGS. 8A through 8C and 9A through 9C.

In Embodiment 3, methods for selectively removing a peripheral portion of the flowable film obtained in Embodiment 1 or 2 are described. Specifically, in a first method, the peripheral portion is removed by supplying a solution for dissolving the flowable film to the peripheral portion of the flowable film while rotating the substrate on which the flowable film is formed, and in a second method, the peripheral portion of the flowable film is modified by irradiating the peripheral portion with light and thereafter the modified peripheral portion is removed.

In Embodiment 1 or 2, the flowable film is formed over the whole surface of the substrate, namely, also on a peripheral portion of the substrate. However, it is sometimes necessary to mechanically hold the peripheral portion of the substrate.

Embodiment 3 is devised for overcoming such a problem, and since the peripheral portion of the flowable film is selectively removed in Embodiment 3, the peripheral portion of the substrate can be easily mechanically held.

Now, the first method for selectively removing the peripheral portion of a flowable film 22 will be described with reference to FIGS. 8A through 8C.

First, as shown in FIG. 8A, after a substrate 21 on which the flowable film 22 is formed is held through vacuum adsorption on a rotatable stage 20, the stage 20 is rotated for rotating the flowable film 22, a release solution 33 is supplied from a first nozzle 31 to the peripheral portion of the flowable film 22 and a release solution 34 is supplied from a second nozzle 32 to the back surface of the peripheral portion of the substrate 21.

Thus, as shown in FIG. 8B, the peripheral portion of the flowable film 22 can be removed as well as the material with flowability having been adhered onto the peripheral portion of the back surface of the substrate 21 can be removed.

Next, while continuously rotating the stage 20, the supply of the release solutions 33 and 34 is stopped, so as to dry the flowable film 22. In this manner, as shown in FIG. 8C, the flowable film 22 whose peripheral portion has been selectively removed can be obtained.

It is noted that the first method is preferably performed before the transferring process for the flowable film 22.

Since the peripheral portion of the flowable film 22 is removed while rotating the stage 20 together with the flowable film 22 in the first method, this method is suitable when the plane shape of the substrate 21 is in the shape of a circle or a polygon with a large number of vertexes.

Now, the second method for selectively removing the peripheral portion of a flowable film 22 will be described with reference to FIGS. 9A through 9C.

First, as shown in FIG. 9A, after a substrate 21 on which the flowable film 22 is formed is held through vacuum adsorption on a rotatable stage 20, the stage 20 is rotated for rotating the flowable film 22, and the peripheral portion of the flowable film 22 is irradiated with light 36 emitted from a photoirradiation device 35, so as to modify the peripheral portion by causing a photochemical reaction in the peripheral portion (irradiated portion) of the flowable film 22. The light 36 used in this case is preferably UV or light of a shorter wavelength than UV.

Next, as shown in FIG. 9B, after stopping the rotation of the stage 20 together with the flowable film 22, a solution 37 such as a developer is supplied over the flowable film 22. Thus, the peripheral portion of the flowable film 22 having been modified is dissolved in the solution 37, and hence, the peripheral portion of the flowable film 22 can be selectively removed.

Then, as shown in FIG. 9C, the stage 20 is rotated together with the flowable film 22 again, so as to remove the solution 37 remaining on the flowable film 22 to the outside by using centrifugal force. In this case, while or after removing the solution 37, a rinsing solution is preferably supplied onto the flowable film 22 so as to remove the solution 37 still remaining. In this manner, the flowable film 22 whose peripheral portion has been selectively removed can be obtained.

It is noted that the second method is preferably performed before the transferring process for the flowable film 22.

Since the peripheral portion of the flowable film 22 is selectively irradiated with the light 36 in the second method, this method is applicable not only when the plane shape of the substrate 21 is in the shape of a circle or a polygon with a large number of vertexes but also when it is in the shape of a polygon with a small number of vertexes such as a triangle or a rectangle.

(Embodiment 4)

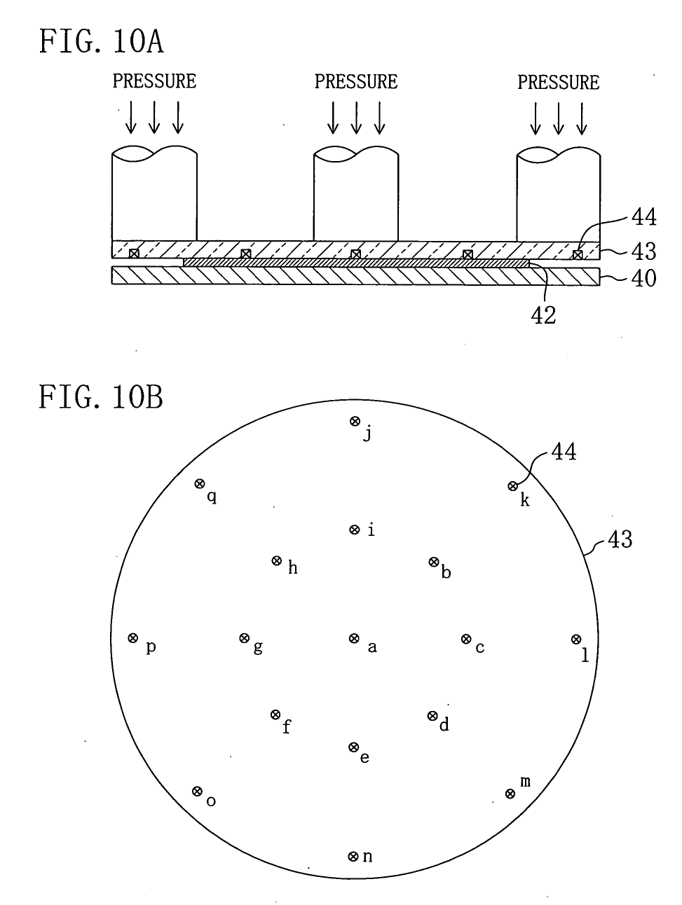

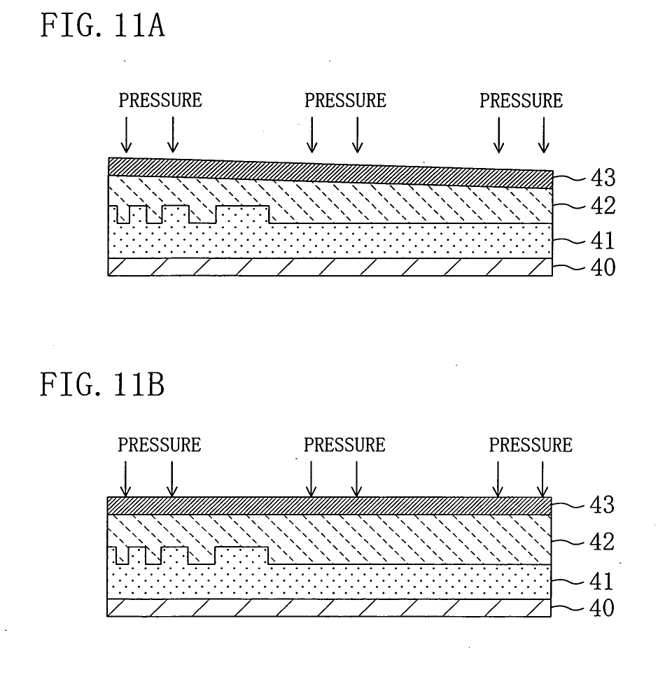

A method for forming a semiconductor device according to Embodiment 4 will now be described with reference to FIGS. 10A, 10B, 11A and 11B.

In Embodiment 4, a preferable method for planarizing the top face of the flowable film obtained in Embodiment 1 or 2 is described, and in this method, a plurality of distances between the surface of the substrate or the stage and the pressing face of the pressing member are measured and the flowable film is pressed in such a manner that these plural distances are equal to one another.

First, as shown in FIG. 10A, after forming a flowable film 42 on a step layer (not shown in the drawing) above a substrate 40 by the method of Embodiment 1 or 2, a pressing member 43 having a plurality of distance sensors 44 on its flat pressing face is used for planarizing the top face of the flowable film 42. In Embodiment 4, the outside dimension of the stage 20 (see FIG. 4C or 5B) is preferably larger than that of the substrate 40.

In this case, a plurality of distances between the surface of the substrate 40 or the surface of the stage 20 (see FIG. 4C or 5B) on which the substrate 40 is placed and the pressing face of the pressing member 43 are measured with the plural distance sensors 44, and the flowable film 42 is planarized by pressing the flowable film 42 with the pressing member 43 in such a manner that the plural distances are equal to one another. Specifically, information of the plural distances measured with the plural distance sensors 44 is fed back to pressing means for pressing the pressing member 43, so that the flowable film 42 can be pressed in such a manner that the plural distances are equal to one another. The feedback control may be executed by using a computer. Also, in measuring the plural distances between the surface of the substrate 40 or the surface of the stage 20 (see FIG. 4C or 5B) on which the substrate 40 is placed and the pressing face of the pressing member 43, each distance is preferably measured by measuring capacitance per unit area in the corresponding measurement position. Thus, the plural distances can be easily and definitely measured.

Now, the method for measuring the plural distances between the surface of the substrate 40 and the pressing face of the pressing member 43 will be described with reference to FIG 10B.

In FIG. 10B, a, b, c, . . . and q denote positions where the distance sensors 44 are respectively provided. The positions a through q are preferably optimized in accordance with the mechanism of the pressing member 43 so as to be set to positions where the distances between the surface of the substrate 40 or the surface of the stage where the substrate 40 is placed and the surface of the flowable film 42 can be efficiently measured. For example, the sensor positions a through i at the center are suitable to measure the distances between the surface of the substrate 40 and the surface of the flowable film 42, and the sensor positions j through q in the peripheral portion are suitable to measure the distances between the surface of the stage where the substrate 40 is placed and the surface of the flowable film 42.

Accordingly, merely the distances between the surface of the substrate 40 and the surface of the flowable film 42 may be measured with the distance sensors 44 provided in the sensor positions a through i alone, merely the distances between the surface of the stage where the substrate 40 is placed and the surface of the flowable film 42 may be measured with the distance sensors 44 provided in the sensor positions j through q alone, or the distances between the surface of the substrate 40 and the surface of the flowable film 42 and the distances between the surface of the stage where the substrate 40 is placed and the surface of the flowable film 42 may be measured with the distance sensors 44 provided in the sensor positions a through q.

Alternatively, in the case where the pressing face of the pressing member 44 can be finely adjusted, after the distances between the surface of the substrate 40 and the surface of the flowable film 42 are adjusted with the distance sensors 44 provided in the sensor positions a through i, the distances between the surface of the substrate 40 and the surface of the flowable film 42 may be adjusted with the distance sensors 44 provided in the sensor positions j through q. Thus, more highly accurate flatness can be realized. It is noted that the number and the positions of the distance sensors 44 may be optimized in accordance with a desired degree of flatness.

In Embodiment 1, it is significant but is not easy to equalize a distance of the surface of the flowable film 12A from the surface of the substrate 10. In other words, in Embodiment 1, the distance of the surface of the flowable film 12A from the surface of the substrate 10 can be made uniform by previously setting the distance between the surface of the substrate 10 and the pressing face of the pressing member 13 to be uniform. However, in this method, it is necessary to set the distance between the surface of the substrate 10 and the pressing face of the pressing member 13 to be uniform every given period of time, namely, every time the pressing face of the pressing member 13 has pressed a given number of flowable films 12A.

However, in Embodiment 4, the distance of the surface of the flowable film 42 from the surface of the substrate 40 can be always uniform, and hence, an operation for making the distance between the surface of the substrate 40 and the pressing face of the pressing member 43 uniform every given period of time can be omitted.

The process for adjusting the distance between the surface of the substrate 40 and the pressing face of the pressing member 43 to be uniform may be performed before, while or after pressing the flowable film 42 with the pressing member 43.

FIG. 11A shows a cross-section of the flowable film 42 obtained when the distance between the pressing face of the pressing member 43 and the surface of the substrate 40 provided below a step layer 41 is ununiform, and FIG. 11B shows a cross-section of the flowable film 42 obtained when the distance between the pressing face of the pressing member 43 and the surface of the substrate 40 is kept uniform.

As is understood from comparison between FIGS. 11A and 11B, when the flowable film 42 is pressed with the distance between the pressing face of the pressing member 43 and the surface of the substrate 10 kept uniform, the top face of the flowable film 42 can be planarized with the distance of the flowable film 42 from the surface of the substrate 40 kept uniform.

(Embodiment 5)

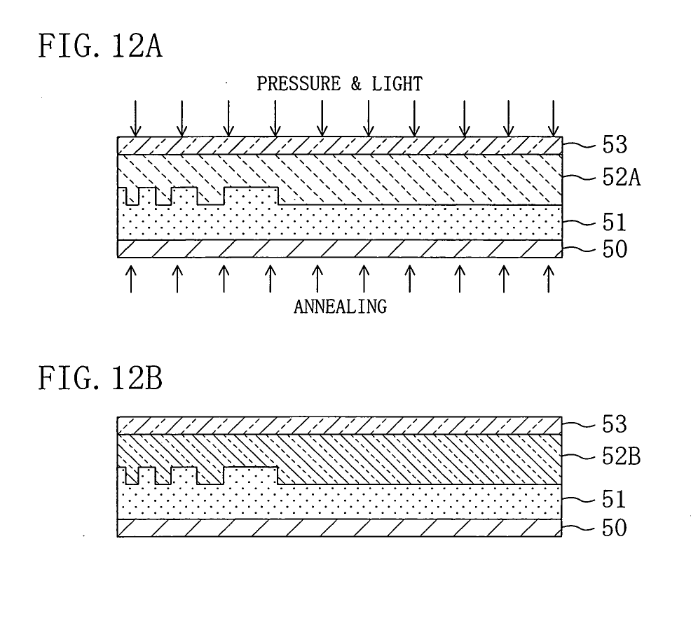

A method for forming a semiconductor device according to Embodiment 5 will now be described with reference to FIGS. 12A and 12B.

In the method of Embodiment 5, a flowable film 52A is solidified by annealing the flowable film 52A while irradiating it with light.

As shown in FIG. 12A, while pressing a flat pressing face of a pressing member 53, which is made of a light transmitting material such as quartz, against the flowable film 52A formed on a step layer 51 above a substrate 50, so as to planarize the top face of the flowable film 52A, the flowable film 52A is irradiated with light and annealed. The light used for the irradiation is, when the flowable film 52A is solidified principally through a photochemical reaction, preferably UV or light of a shorter wavelength than UV, and when the flowable film 52A is solidified principally through a thermal chemical reaction, preferably infrared light.

Thus, the flowable film 52A is solidified through the photochemical reaction or the thermal chemical reaction, resulting in giving a solidified film 52B as shown in FIG. 12B.

The method for solidifying the flowable film 52A principally through the photochemical reaction is suitable to a film of a photo-setting resin, such as a photosensitive resin film like a photoresist used in the lithography. Also, the method for solidifying the flowable film 52A principally through the thermal chemical reaction is suitable to an organic film, an organic-inorganic film or an inorganic film made of a chemically amplified material composed of a material for generating an acid or a base through irradiation with light and a base polymer solidified by an acid or a base.

(Embodiment 6)

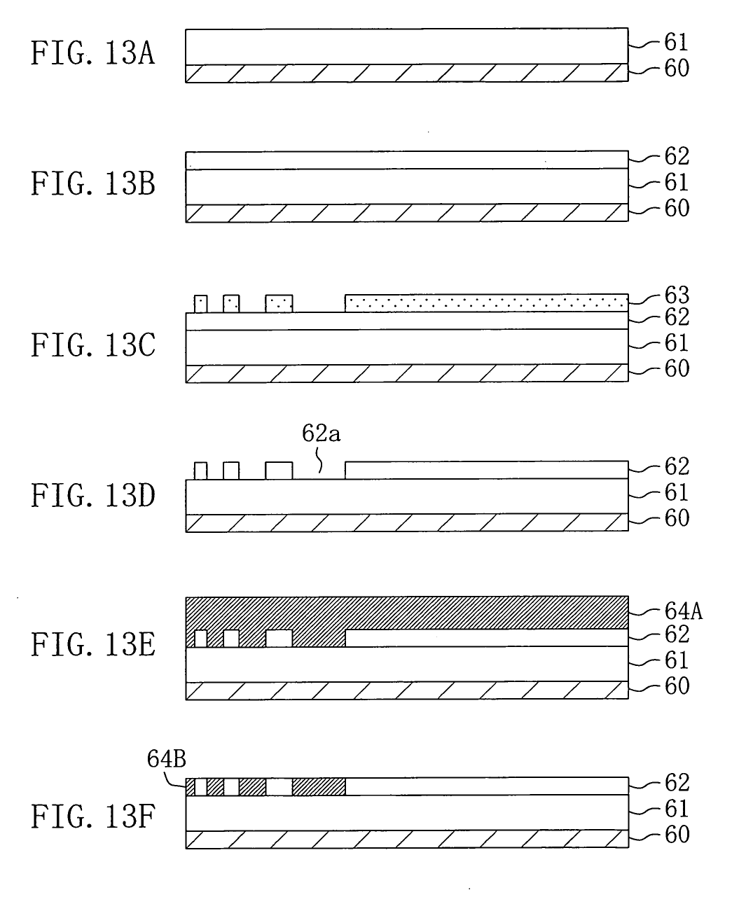

A method for forming a semiconductor device according to Embodiment 6 will now be described with reference to FIGS. 13A through 13F, 14A through 14D, 15A through 15D and 16A through 16D.

First, after forming an interlayer insulating film 61 on a substrate 60 as shown in FIG. 13A, an organic film 62 of, for example, a photoresist film, an organic low-k film or the like is formed on the interlayer insulating film 61 by the spin coating method or the chemical vapor deposition (CVD) method as shown in FIG. 13B. In this case, the organic film 62 preferably includes a material having an antireflection function corresponding to the wavelength of exposing light used in subsequently performed lithography. Thus, a process for forming an antireflection film below the organic film 62 can be omitted.

Instead of the organic film 62, an inorganic film or an organic-inorganic film may be used. For example, an SOG film or the like formed by the spin coating method may be used. In particular, an SOG film that is not completely crosslinked but partly unreacted through baking at a temperature of approximately 200° C. through approximately 300° C. is used. Alternatively, an SOD (spin-on-dielectric) film recently frequently used as a low-k film material may be used.

Next, after forming a fist resist pattern 63 having an interconnect groove forming opening on the organic film 62 as shown in FIG. 13C, the organic film 62 is dry etched by using the first resist pattern 63 as a mask, so as to form an interconnect groove 62a in the organic film 62 as shown in FIG. 13D. In this dry etching, an etching gas including, as a principal component, a mixed gas of an oxygen gas and a nitrogen gas or a mixed gas of a nitrogen gas and a hydrogen gas can be used.

Then, after forming a barrier metal layer (not shown in the drawing) on the organic film 62 including the inside of the interconnect groove 62a by the sputtering method as shown in FIG. 13E, a first metal film 64A of Cu, Ag, Au, Pt or the like is deposited on the barrier metal layer by, for example, the plating method.

Next, as shown in FIG. 13F, an unnecessary portion of the first metal film 64A, namely, a portion thereof exposed above the organic film 62, is removed by the CMP, so as to form a buried interconnect 64B made of the first metal film 64A.

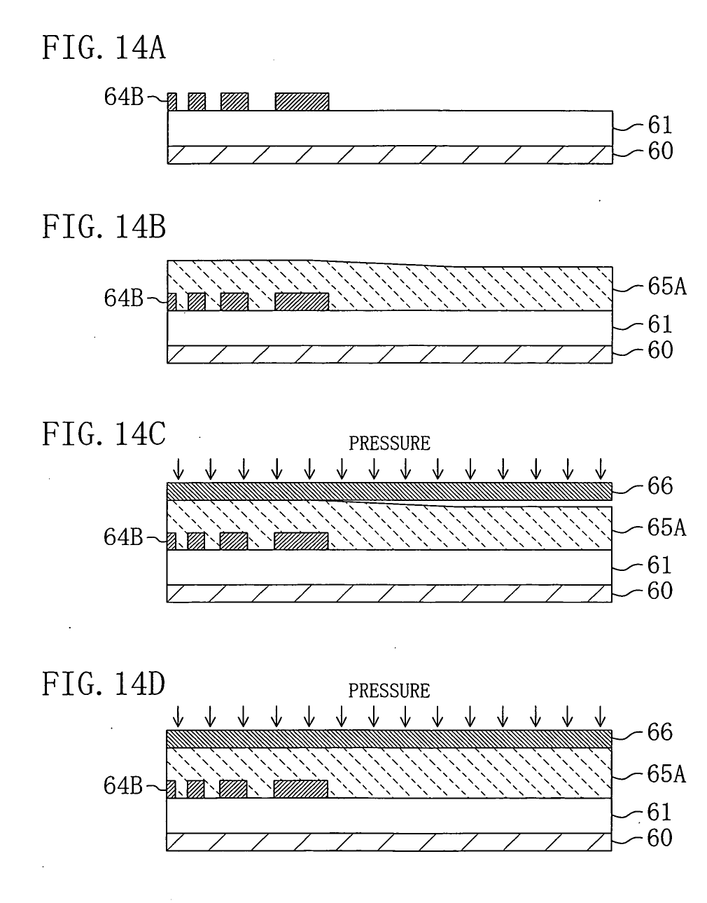

Then, as shown in FIG. 14A, dry etching is performed for removing the organic film 62 and exposing the buried interconnect 64B. Thereafter, a diffusion preventing film (not shown in the drawing) is formed on the buried interconnect 64B by, for example, the CVD. It is noted that the dry etching of the organic film 62 may be anisotropic or isotropic. Also, as the diffusion preventing film, a single-layer film of a Si₃N₄ film, a SiC film or a SiCN film, or a multilayered film of such a film and a SiCO film can be used.

Next, as shown in FIG. 14B, a flowable film 65A is formed on the buried interconnect 64B having the diffusion preventing film by supplying an insulating material with flowability in the form of a liquid or a gel by the spin coating method, the microscopic spraying method, the rotation roller method or the like in the same manner as in Embodiment 1. The thickness of the flowable film 65A can be appropriately set.

The flowable film 65A may be any of the insulating films described in Embodiment 1, namely, an organic film, an inorganic film, an organic-inorganic film or a porous film. When such an insulating film is used, the resultant insulating film attains a lower dielectric constant than a general silicon oxide film, and thus, a film suitable to a semiconductor device refined to 100 nm or less can be realized. In particular, when a porous film is used as the flowable film 65A, an insulating film with a very low dielectric constant of 2 or less can be realized.

Next, as shown in FIG. 14C, after a flat pressing face of a pressing member 66 is brought into contact with the surface of the flowable film 65A, a pressure is applied to the pressing member 66 so as to planarize the top face of the flowable film 65A as shown in FIG. 14D. In other words, the top face of the flowable film 65A is made to be placed at the uniform height from the surface of the substrate 61.

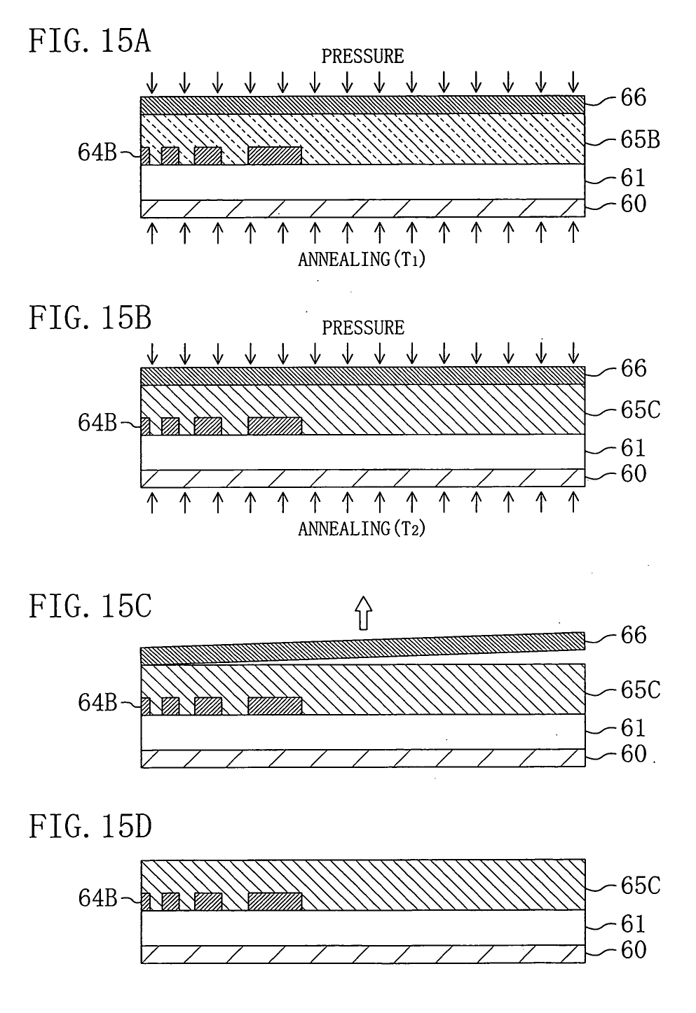

Then, as shown in FIG. 15A, the substrate 60 together with the flowable film 65A are annealed at a first temperature (T1) so as to cause a thermal chemical reaction in the insulating material. Thus, the flowable film 65A is solidified to form a solidified film 65B with a flat top face. In the solidifying process, any of the methods of Embodiments 1 through 4 suitable to the characteristics of the flowable film 65A may be selected.

Next, as shown in FIG. 15B, in the same manner as in Embodiments 1 and 2, the solidified film 65B is annealed at a second temperature (T2) higher than the first temperature (T1) for burning the solidified film 65B, so as to form a burnt film 65C that is made of the solidified film 65B burnt and has a flat top face. Thereafter, after the temperature of the burnt film 65C is lowered to a temperature range from approximately 100° C. to room temperature, as shown in FIG. 15C, the pressing member 66 is moved away from the burnt film 65C and the temperature of the burnt film 65C is lowered ultimately to room temperature. In this manner, as shown in FIG. 15D, the burnt film 65C having a flat top face is obtained. In the case where the burnt film 65C is desired to be formed in a small thickness, the burnt film 65C is subjected to the CMP or the etch back process.

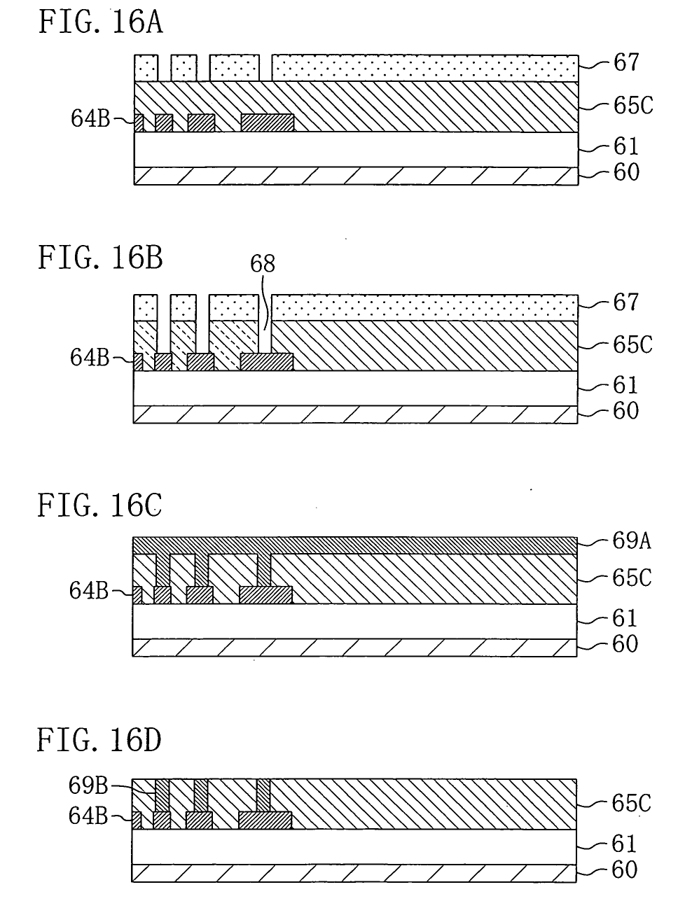

Then, as shown in FIG. 16A, after forming a second resist pattern 67 having a via hole forming opening on the burnt film 65C, the burnt film 65C is dry etched by using the second resist pattern 67 as a mask, so as to form a via hole 68 in the burnt film 65C as shown in FIG. 16B. In this dry etching, an etching gas including fluorine, such as a CF₄ gas or a CHF₃ gas, can be used. Thereafter, the diffusion preventing film (not shown in the drawing) formed on the buried interconnect 64B is dry etched, so as to expose the buried interconnect 64B.

Next, as shown in FIG. 16C, after depositing a barrier metal layer (not shown in the drawing) of Ta or TaN over the burnt film 65C including the inside of the via hole 68 by the sputtering method or the CVD, a second metal film 69A of, for example, copper is deposited over the barrier metal layer by, for example, the plating method. When the second metal film 69A is deposited by the plating method, the second metal film 69A is preferably grown by using, as a seed, a seed layer previously formed on the barrier metal layer by the sputtering. It is noted that the second metal film 69A may be deposited by the CVD or the like instead of the plating method and that silver, gold, platinum or the like may be used instead of copper. These metals are preferred because they can be easily deposited by the plating method and have low resistance.

Then, an unnecessary portion of the second metal film 69A, namely, a portion thereof exposed above the burnt film 62C, is removed by the CMP. Thus, a buried plug 69B made of the second metal film 69A is obtained.

Since the burnt film 65C with no global level difference can be formed in Embodiment 6, local concentration of the film can be released in the insulating film, resulting in improving the reliability of the multilayered interconnects. Also, since the burnt film 65C having a flat top face can be obtained, in the case where a mask pattern is formed on the burnt film 65C by the lithography, degradation of a focal depth margin derived from a level difference can be suppressed. Therefore, as compared with conventional technique, a process margin (process window) can be increased, resulting in forming a highly accurate semiconductor device.

In the case where the solidified film 65B largely outgassing is burnt in Embodiment 6, the burning process of Embodiment 2 is more effectively employed than that of Embodiment 1. In the case where the flowable film 65A is made of a general film, the concentration of a solvent remaining in the flowable film 65A can be controlled through the pre-bake, and hence, the film minimally outgases in the burning process. However, depending upon the composition of the flowable film 65A, the film may largely outgas in some cases in the burning process where the film is annealed at a comparatively high temperature. In such a case, when the burning process of Embodiment 1 is employed, there arises a problem of uniformity or stability in the burnt film, and hence, the burning process of Embodiment 2 is preferably employed.

In particular, when the burnt film 65C is a porous film, the effect of the burning process of Embodiment 2 is exhibited. In a porous film, most of the basic structure of the solidified film 65B is formed in the annealing performed at the first temperature (T1) of the solidifying process, and a pore forming material added for forming pores is vaporized in the annealing performed at the second temperature (T2). of the following burning process. Therefore, the burning process of Embodiment 2 where the film is burnt with the pressing member 66 moved away from the solidified film 65B is suitable. However, even in using a porous film, when a material in which the basic skeleton of the film is formed and a pore forming material is vaporized simultaneously in the solidifying process is used, a good burnt film 65C can be obtained even by employing the burning process of Embodiment 1.

Since the burnt film 65C is used as an insulating film of a semiconductor device in Embodiment 6, the annealing temperature of the solidifying process (the first temperature) is preferably approximately 150° C. through 300° C., and the annealing temperature of the burning process (the second temperature) is preferably approximately 350° C. through 450° C.

(Embodiment 7)

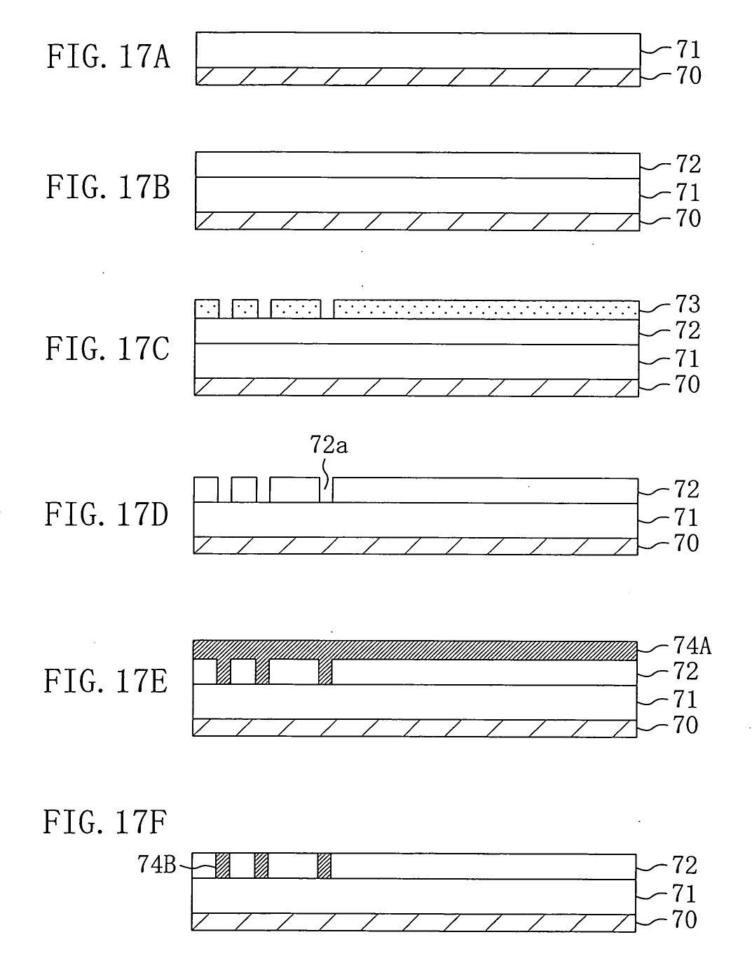

A method for forming a semiconductor device according to Embodiment 7 will now be described with reference to FIGS. 17A through 17F, 18A through 18D, 19A through 19D and 20A through 20D.

First, after forming an interlayer insulating film 71 on a substrate 70 as shown in FIG. 17A, an organic film 72 of, for example, a photoresist film, an organic low-k film or the like is formed on the interlayer insulating film 71 by the spin coating method or the chemical vapor deposition (CVD) method as shown in FIG. 17B.

Instead of the organic film 72, an inorganic film or an organic-inorganic film may be used. For example, an SOG film or the like formed by the spin coating method may be used. In particular, an SOG film that is not completely crosslinked but partly unreacted through baking at a temperature of approximately 200° C. through approximately 300° C. is used. Alternatively, an SOD (spin-on-dielectric) film recently frequently used as a low-k film material may be used.

Next, after forming a fist resist pattern 73 having a via hole forming opening on the organic film 72 as shown in FIG. 17C, the organic film 72 is dry etched by using the first resist pattern 73 as a mask, so as to form a via hole 72a in the organic film 72 as shown in FIG. 17D.

Then, after forming a barrier metal layer (not shown in the drawing) on the organic film 72 including the inside of the via hole 72a by the sputtering method as shown in FIG. 17E, a first metal film 74A of Cu, Ag, Au, Pt or the like is deposited on the barrier metal layer by, for example, the plating method.

Next, as shown in FIG. 17F, an unnecessary portion of the first metal film 74A, namely, a portion thereof exposed above the organic film 72, is removed by the CMP, so as to form a buried plug 74B made of the first metal film 74A.

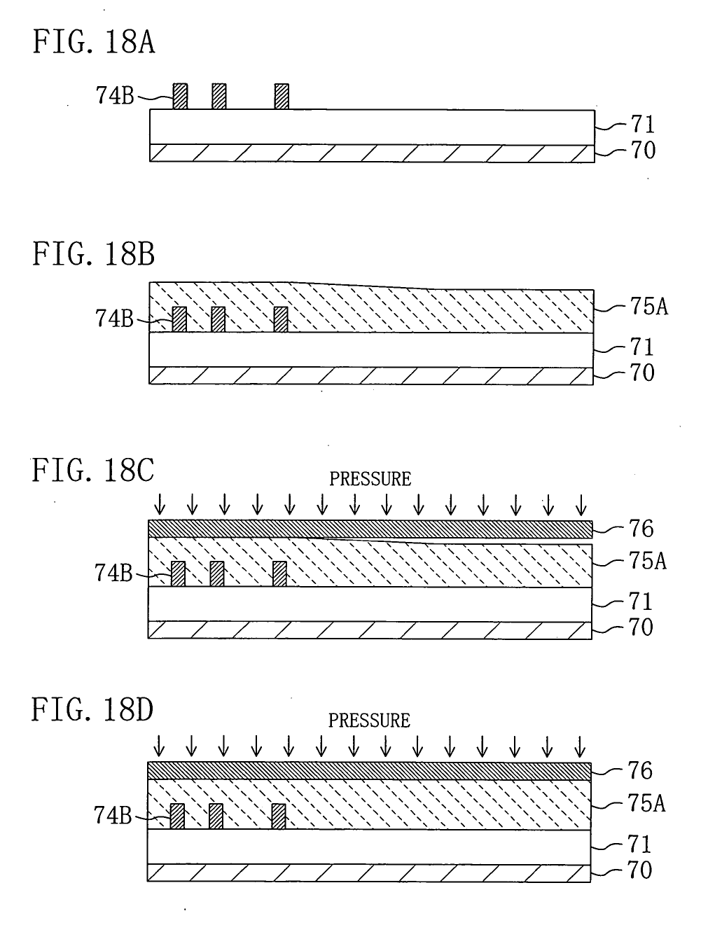

Then, as shown in FIG. 18A, dry etching is performed for removing the organic film 72 and exposing the buried plug 74B. Thereafter, a diffusion preventing film (not shown in the drawing) is formed on the buried plug 74B by, for example, the CVD.

Next, as shown in FIG. 18B, a flowable film 75A is formed on the buried plug 74B having the diffusion preventing film by supplying an insulating material with flowability in the form of a liquid or a gel by the spin coating method, the microscopic spraying method, the rotation roller method or the like in the same manner as in Embodiment 1. The flowable film 75A may be any of the insulating films described in Embodiment 1, namely, an organic film, an inorganic film, an organic-inorganic film or a porous film.

Next, as shown in FIG. 18C, after a flat pressing face of a pressing member 76 is brought into contact with the surface of the flowable film 75A, a pressure is applied to the pressing member 76 so as to planarize the top face of the flowable film 75A as shown in FIG. 18D.

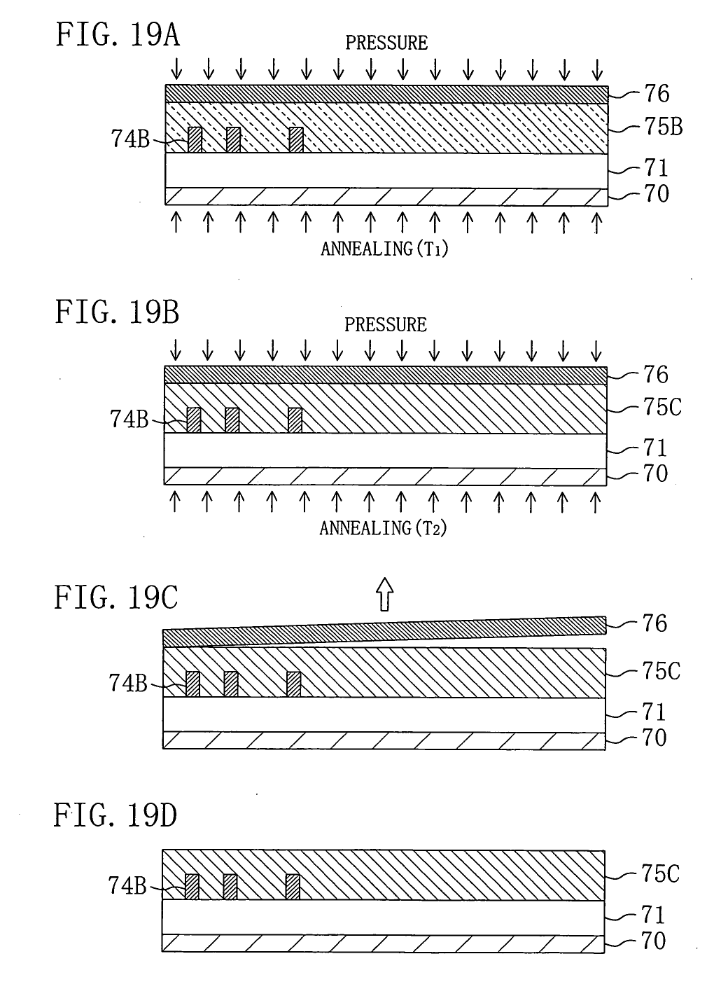

Then, as shown in FIG. 19A, the substrate 70 together with the flowable film 75A are annealed at a first temperature (T1) so as to cause a thermal chemical reaction in the insulating material. Thus, the flowable film 75A is solidified to form a solidified film 75B with a flat top face. In the solidifying process, any of the methods of Embodiments 1 through 4 suitable to the characteristics of the flowable film 75A may be selected.

Next, as shown in FIG. 19B, in the same manner as in Embodiments 1 and 2, the solidified film 75B is annealed at a second temperature (T2) higher than the first temperature (T1) for burning the solidified film 75B, so as to form a burnt film 75C that is made of the solidified film 75B burnt and has a flat top face. Thereafter, after the temperature of the burnt film 75C is lowered to a temperature range from approximately 100° C. to room temperature, as shown in FIG. 19C, the pressing member 76 is moved away from the burnt film 75C and the temperature of the burnt film 75C is lowered ultimately to room temperature. In this manner, as shown in FIG. 19D, the burnt film 75C having a flat top face is obtained.

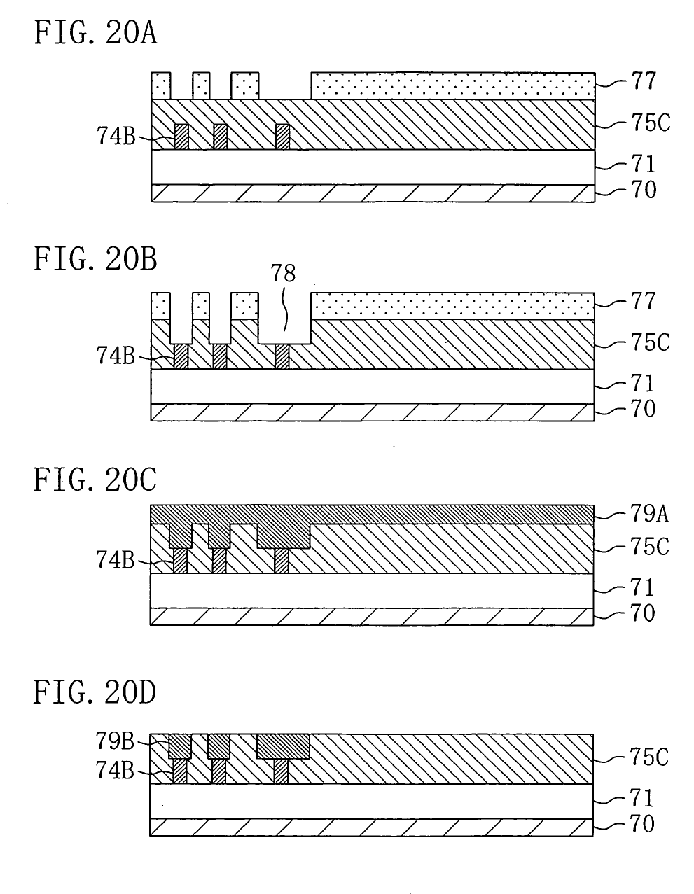

Then, as shown in FIG. 20A, after forming a second resist pattern 77 having an interconnect groove forming opening on the burnt film 75C, the burnt film 75C is dry etched by using the second resist pattern 77 as a mask, so as to form an interconnect groove 78 in the burnt film 75C as shown in FIG. 20B. Thereafter, the diffusion preventing film (not shown in the drawing) formed on the buried plug 74B is dry etched, so as to expose the buried plug 74B.

Next, as shown in FIG. 20C, after depositing a barrier metal layer (not shown in the drawing) of Ta or TaN over the burnt film 75C including the inside of the interconnect groove 78 by the sputtering method or the CVD, a second metal film 79A of, for example, copper is deposited over the barrier metal layer by, for example, the plating method.

Then, an unnecessary portion of the second metal film 79A, namely, a portion thereof exposed above the burnt film 75C, is removed by the CMP. Thus, a buried interconnect 79B made of the second metal film 79A is obtained.

Since the burnt film 75C with no global level difference can be formed in Embodiment 7, local concentration of stress can be released in the insulating film, resulting in improving the reliability of the multilayered interconnects. Also, since the burnt film 75C having a flat top face can be obtained, in the case where a mask pattern is formed on the burnt film 75C by the lithography, degradation of a focal depth margin derived from a level difference can be suppressed. Therefore, as compared with conventional technique, a process margin (process window) can be increased, resulting in forming a highly accurate semiconductor device.

Since the burnt film 75C is used as an insulating film of a semiconductor device in Embodiment 7, the annealing temperature of the solidifying process (the first temperature) is preferably approximately 150° C. through 300° C., and the annealing temperature of the burning process (the second temperature) is preferably approximately 350° C. through 450° C.

1. A method for forming a semiconductor device comprising the steps of:
forming, on a substrate, a flowable film made of an insulating material with flowability;
planarizing a top face of the flowable film by pressing the flowable film with a pressing member;
forming a solidified film by annealing the flowable film at a first temperature with the pressing member pressed against the flowable film; and
forming a burned film with a flat top face by burning the solidified film through annealing of the solidified film at a second temperature higher than the first temperature.

2. A method for forming a semiconductor device comprising the steps of:
forming a flowable film made of an insulating material with flowability on a substrate including a interconnect;
planarizing a top face of the flowable film by pressing the flowable film with a pressing member;
forming a solidified film by annealing the flowable film at a first temperature with the pressing member pressed against the flowable film;
forming a burned film with a flat top face by burning the solidified film through annealing of the solidified film at a second temperature higher than the first temperature;
forming a via hole in the burned film; and
forming a plug connected at least to the interconnect by filling the via hole with a metal material.

3. A method for forming a semiconductor device comprising the steps of:
forming a flowable film made of an insulating material with flowability on a substrate including a plug;
planarizing a top face of the flowable film by pressing the flowable film with a pressing member;
forming a solidified film with a flat top face by annealing the flowable film at a first temperature with the pressing member pressed against the flowable film;
forming a burned film with a flat top face by burning the solidified film through annealing of the solidified film at a second temperature higher than the first temperature;
forming a groove in the burned film; and
forming a interconnect connected at least to the plug by filling the groove with a metal material.

4. The method for forming a semiconductor device of claims 1,
wherein the first temperature is approximately 150° C. through approximately 300° C.

5. The method for forming a semiconductor device of claims 2,
wherein the first temperature is approximately 150° C. through approximately 300° C. and the second temperature is approximately 350° C. through approximately 450° C.

6. The method for forming a semiconductor device of claims 1,
wherein the second temperature is approximately 350° C. through approximately 450° C.

7. The method for forming a semiconductor device of claims 1
wherein the insulating material with flowability is in the form of a liquid or a gel.

8. The method for forming a semiconductor device of claims 1,
wherein in the step of forming a flowable film, the flowable film is formed on the substrate by supplying the insulating material with flowability onto the substrate rotated.

9. The method for forming a semiconductor device of claims 1,
wherein in the step of forming a flowable film, the flowable film is formed on the substrate by supplying the insulating material with flowability onto the substrate and rotating the substrate after the supply.

10. The method for forming a semiconductor device of claims 1,
wherein in the step of forming a flowable film, the flowable film is formed on the substrate by supplying, in the form of a shower or a spray, the insulating material with flowability onto the substrate rotated.

11. The method for forming a semiconductor device of claims 1,
wherein in the step of forming a flowable film, the flowable film is formed on the substrate by supplying the insulating material with flowability from a fine spray vent of a nozzle onto the substrate with the nozzle having the fine spray vent and the substrate relatively moved along plane directions.

12. The method for forming a semiconductor device of claims 1,
wherein in the step of forming a flowable film, the flowable film is formed on the substrate by supplying the insulating material with flowability having been adhered to a surface of a roller onto the substrate with the roller rotated.

13. The method for forming a semiconductor device of claims 1, further comprising, between the step of forming a flowable film and the step of planarizing a top face of the flowable film, a step of selectively removing a peripheral portion of the flowable film.

14. The method for forming a semiconductor device of claim 13,
wherein the step of selectively removing a peripheral portion of the flowable film is performed by supplying a solution for dissolving the insulating material with flowability onto the peripheral portion of the flowable film with the flowable film rotated.

15. The method for forming a semiconductor device of claim 13,
wherein the step of selectively removing a peripheral portion of the flowable film is performed by modifying the peripheral portion of the flowable film through irradiation with light and removing the modified peripheral portion.

16. The method for forming a semiconductor device of claim 1,
wherein in the step of planarizing a top face of the flowable film, a plurality of distances between a surface of the substrate and the pressing member are measured, and the flowable film is pressed with the pressing member in such a manner that the plurality of distances are equal to one another.

17. The method for forming a semiconductor device of claim 16,
wherein the plurality of distances are measured by measuring capacitance per unit area in respective measurement positions.

18. The method for forming a semiconductor device of claim 1,
wherein in the step of planarizing a top face of the flowable film, a plurality of distances between a surface of a stage where the substrate is placed and the pressing member are measured, and the flowable film is pressed with the pressing member in such a manner that the plurality of distances are equal to one another.

19. The method for forming a semiconductor device of claim 18,
wherein the plurality of distances are measured by measuring capacitance per unit area in respective measurement positions.

20. The method for forming a semiconductor device of claim 1,
wherein the pressing member of the pressing member has a hydrophobic property.

21. The method for forming a semiconductor device of claim 1,
wherein the insulating material with flowability is a photo-setting resin, and the step of forming a solidified film includes a sub-step of irradiating the flowable film with light.

22. The method for forming a semiconductor device of claim 1,
wherein the insulating material with flowability is an organic material, an inorganic material, an organic-inorganic material, a photo-setting resin or a photosensitive resin.

23. The method for forming a semiconductor device of claim 1,
wherein in the step of forming a burnt film, the solidified film is annealed at the second temperature with the pressing member pressed against the solidified film.

24. The method for forming a semiconductor device of claim 1,
wherein in the step of forming a burnt film, the solidified film is annealed at the second temperature with the pressing member moved away from the solidified film.

25. The method for forming a semiconductor device of claim 1,
wherein the burnt film is a porous film.

26. The method for forming a semiconductor device of claim 1,
wherein the burnt film has a dielectric constant of approximately 4 or less.

27. The method for forming a semiconductor device of claim 2, further comprising, before the step of forming a flowable film, a step of forming the buried interconnect exposed on the substrate by forming a buried interconnect in an organic film formed on the substrate and removing the organic film.

28. The method for forming a semiconductor device of claim 27,
wherein the organic film is removed by wet or dry etching in the step of forming the buried interconnect or the buried plug.

29. The method for forming a semiconductor device of claim 3,
further comprising, before the step of forming a flowable film, a step of forming the buried plug exposed on the substrate by forming a buried plug in an organic film formed on the substrate and removing the organic film.

30. The method for forming a semiconductor device of claim 29,
wherein the organic film is removed by wet or dry etching in the step of forming the buried interconnect or the buried plug.
